(19) United States
(12) Patent Application Publication
(10) Pub. No.: US 2022/0228250 A1
(43) Pub. Date: Jul. 21, 2022

(54) CRUCIBLE AND VAPOR DEPOSITION APPARATUS

(71) Applicant: Phoenix Silicon International Corp., Hsinchu (TW)

(72) Inventors: CHIEN-HSIUNG HUANG, Hsinchu (TW); CHAO-TSUNG TSOU, Hsinchu (TW); CHENG-YEN LIN, Hsinchu (TW)

(21) Appl. No.: 17/149,824

(22) Filed: Jan. 15, 2021

(51) Int. Cl. C23C 14/24

(52) U.S. Cl. CPC C23C 14/243

(57) ABSTRACT

A crucible includes a crucible body and at least one protrusion. The crucible body has a containing groove. The protrusion is disposed on an outer wall surface of the crucible body. The protrusion protrudes outward from the outer wall of the crucible body. A vapor deposition apparatus includes a metal base and a crucible. The crucible is disposed in the metal base. The crucible includes a crucible body and at least one protrusion. The crucible body has a containing groove, and the containing groove is used for adding a vapor deposition material. The protrusion is disposed on an outer wall surface of the crucible body. The protrusion protrudes outward from the outer wall of the crucible body, and the protrusion abuts the inner wall of the metal base.

### TECHNICAL FIELD

The invention relates to a crucible and a vapor deposition apparatus.

### BACKGROUND

As a kind of container, the crucible is mainly used for burning solid materials, and can be used for the vapor deposition, concentration or crystallization of materials, such as the vapor deposition process. During the vapor deposition process, the production line operator will first place the crucible in the oxygen-free copper base in the machine, and then add the vapor deposition material to the crucible. Then, the subsequent process operations are continued to do, the wafer is placed on the plating pot, and then the chamber door is closed to perform the vapor deposition process. After the process is over, the production line operator first take out the product, and then add the required vapor deposition materials to the crucible again. Then, the aforementioned vapor deposition process is continued to repeat production mode.

However, because the crucible is placed in the heating container by the production line operator, human factors cannot be effectively controlled. It is easy to cause the crucible to be placed incorrectly, causing the position of the crucible to shift, so that one side of the crucible leans against the wall of the oxygen-free copper base. When the crucible is leaning against the wall of the copper base, it is easy to cause the side of the crucible against the copper base to cool faster. That is, one side of the crucible that is not against the wall is heated differently from the other side of the crucible that is against the wall, resulting in uneven heating.

Moreover, since the side of the crucible against the wall cools faster, the power usage of the side of the crucible against the wall during the manufacturing process will be greater than that of the side of the crucible not against the wall. Otherwise the power supply is easy to jump and unstable. In other words, when the crucible is leaning against the wall of the copper base, the power cannot be controlled stably during the manufacturing process.

Furthermore, the crucible against the wall of the copper base is also easier to damage. The service life of the crucible is not only reduced, but the damaged crucible needs to be replaced immediately, which will also increase the production cost.

Therefore, how to improve and provide a crucible and a vapor deposition apparatus to avoid the above-mentioned problems is an issue to be solved in the industry.

### SUMMARY

The present invention provides a crucible and a vapor deposition apparatus, which can uniformly heat the materials in the crucible, can stably control the power supply, increase the service life of the crucible, and reduce production costs.

One embodiment of the present invention provides a crucible including a crucible body and at least one protrusion. The crucible body has a containing groove. The protrusion is disposed on an outer wall surface of the crucible body. The protrusion protrudes outward from the outer wall of the crucible body.

A further embodiment of the present invention provides a vapor deposition apparatus including a metal base and a crucible. The crucible is disposed in the metal base. The crucible includes a crucible body and at least one protrusion. The crucible body has a containing groove, and the containing groove is used for adding a vapor deposition material. The protrusion is disposed on an outer wall surface of the crucible body. The protrusion protrudes outward from the outer wall of the crucible body, and the protrusion abuts the inner wall of the metal base.

In a preferred embodiment, the outer wall surface is an outer wall of the crucible body. The protrusion is a ring-shaped protrusion structure protruding outward from the outer wall.

In a preferred embodiment, the outer wall surface is a bottom wall of the crucible body. The protrusion is a ring-shaped protrusion structure protruding outward from the bottom wall.

In a preferred embodiment, the outer wall surface is an outer wall and a bottom wall of the crucible body. Each protrusion comprises a first protrusion and a second protrusion, the first protrusion is a first ring-shaped protrusion structure protruding outward from the outer wall, and the second protrusion is a second ring-shaped protrusion structure protruding outward from the bottom wall.

In a preferred embodiment, the outer wall surface is an outer wall of the crucible body, and the protrusion is arranged along the circumferential direction of the outer wall.

In a preferred embodiment, the outer wall surface is a bottom wall of the crucible body, and the protrusion is arranged along the circumferential direction of the bottom wall.

In a preferred embodiment, the outer wall surface is an outer wall and a bottom wall of the crucible body. A protrusion comprises a first protrusion and a second protrusion, the first protrusion is arranged along the circumferential direction of the outer wall, and the second protrusion is arranged along the circumferential direction of the bottom wall.

In a preferred embodiment, the crucible body includes a filling end surface, a bottom wall and an outer wall. The containing groove is connected to the filling end surface, and the outer wall is connected between the filling end surface and the bottom wall.

In a preferred embodiment, the metal base is a copper base.

Based on the above, in the crucible and the vapor deposition apparatus of the present invention, a protrusion is provided on the outer wall of the crucible, and the outer wall surface can be the outer wall or bottom wall of the crucible body. In this way, no matter how the crucible is placed in the metal base, by the protrusion abutting against the inner wall of the metal base, the crucible can be kept in the middle position of the metal base. And, the crucible will not deviate, nor will one side of the crucible lean against the wall of the oxygen-free copper base. Therefore, when the crucible is used, the materials in the crucible can be uniformly heated, and the power can be stably controlled.

In order to further understand and understand the features, objectives, and functions of the present invention, the embodiments of the present invention are described in detail with reference to the drawings.

### BRIEF DESCRIPTION OF THE DRAWINGS

FIG. 1 is a schematic diagram of an embodiment of the crucible of the present invention.

FIG. 2A is a top view of FIG. 1.

FIG. 2B is a top view of another embodiment of the protrusion of the present invention.

FIG. 3 is a schematic diagram of another embodiment of the crucible of the present invention.

FIG. 4A is a top view of FIG. 3.

FIG. 4B is a top view of the other embodiment of the protrusion of the present invention.

FIG. 5 is a schematic diagram of the other embodiment of the crucible of the present invention.

FIG. 6 is a schematic diagram of an embodiment of the vapor deposition apparatus of the present invention.

### DETAILED DESCRIPTION

The specific implementation of the present invention will be further described below in conjunction with the drawings and embodiments. The following embodiments are only used to illustrate the technical solutions of the present invention more clearly, and cannot be used to limit the protection scope of the present invention.

In the description of each embodiment, when an element is described as “above” and “below” another element, it refers to a situation where it is directly or indirectly above or below the other element, which may contain other elements set in between. The so-called “directly” means that there are no other intermediary elements in between. Descriptions such as “above” or “below” are described based on the drawings, but also include other possible direction changes. For the convenience and clarity of illustration, the thickness or size of each element in the drawings is shown in an exaggerated, omitted, or sketched manner, and the size of each element is not exactly its actual size.

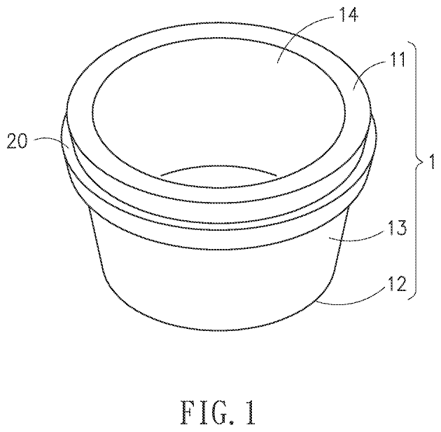

FIG. 1 is a schematic diagram of an embodiment of the crucible of the present invention. Please refer to FIG. 1; the crucible of this embodiment is used for a vapor deposition process. As shown in FIG. 1, the crucible has a crucible body 1 and at least one protrusion 20. The crucible body 1 has a bottom wall 12 and an outer wall 13. The crucible body 1 is a cylindrical container, and the crucible body 1 has a containing groove 14. The crucible body 1 includes a filling end surface 11, the containing groove 14 is connected to the filling end surface 11, and the outer wall 13 is connected between the filling end surface 11 and the bottom wall 12.

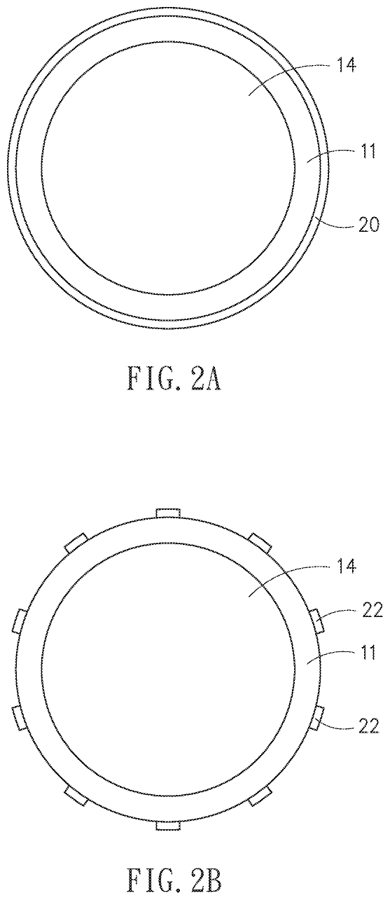

In the embodiment, the protrusion 20 is disposed on the outer wall surface of the crucible body 1, and the protrusion 20 protrudes outward from the outer wall surface of the crucible body 1. The outer wall surface is, for example, the outer wall 13 of the crucible body 1, that is, the protrusion 20 is a ring-shaped protrusion structure protruding outward from the outer wall 13. Refer to FIG. 2A for the ring-shaped protrusion structure. The protrusion 20 forms a ring-shaped protrusion structure around the circumferential direction of the outer wall 13. In addition, as shown in FIG. 1, along the axial direction of the crucible body 1, the protrusion 20 is adjacent to one end of the filling end surface 11. The distance from the protrusion 20 to the bottom wall 12 is greater than the distance from the protrusion 20 to the filling end surface 11, so that the protrusion 20 is farther away from one end of the bottom wall 12; however, the present invention is not limited thereto. In an unillustrated embodiment, the protrusion is adjacent to one end of the bottom wall, that is, the distance from the protrusion to the bottom wall is less than the distance from the protrusion to the filling end surface. Alternatively, the distance from the protrusion to the bottom wall is equal to the distance from the protrusion to the filling end surface.

As shown in FIG. 2B, the number of protrusions 22 can be multiple, and the plurality of protrusions 22 are arranged along the circumferential direction of the outer wall 13. In other words, the protrusion of this embodiment can be a ring-shaped protrusion structure protruding outward from the outer wall 13 as shown in FIG. 1 or FIG. 2A. Alternatively, as shown in FIG. 2B, a plurality of protrusions 22 extend outward on the outer wall 13, and the plurality of protrusions 22 are not connected together. Certainly, in an unillustrated embodiment, part of the protrusions 22 can be connected together, while some of the protrusions 22 are not connected together. In addition, the protrusions 22 can be arranged at the same height position or different height positions adjacent to the bottom wall 12 or far from the bottom wall 12, and can be adjusted depending on the actual product.

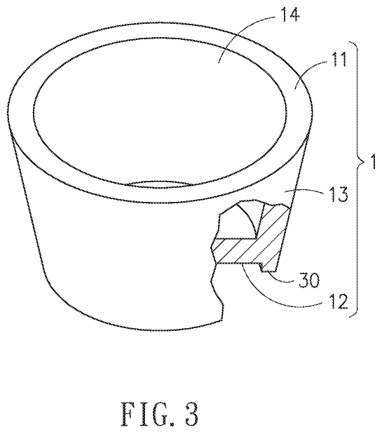

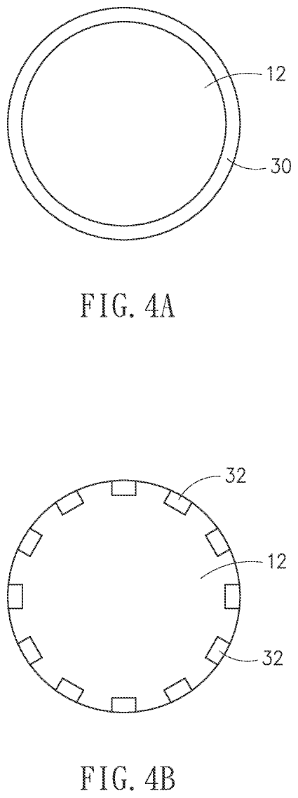

FIG. 3 is a schematic diagram of another embodiment of the crucible of the present invention. Please refer to FIG. 3; it should be noted that the crucible of FIG. 3 is similar to the crucible of FIG. 1, in which the same components are denoted by the same reference numerals and have the same functions, and the description will not be repeated. The difference between the crucible in FIG. 3 and the crucible in FIG. 1 is that the outer wall surface here is the bottom wall 12 of the crucible body 1, that is, the protrusion 30 is a ring-shaped protrusion structure protruding outward from the bottom wall 12. Refer to FIG. 4A for the ring-shaped protrusion structure. The protrusion 30 forms a ring-shaped protrusion structure around the circumferential direction of the bottom wall 12, and the ring-shaped protrusion structure is disposed on the edge side of the bottom wall 12. However, the present invention is not limited thereto. In an unillustrated embodiment, the ring-shaped protrusion structure can be disposed inside the bottom wall 12.

As shown in FIG. 4B, the number of protrusions 32 can be multiple, and the plurality of protrusions 32 are arranged along the circumferential direction of the bottom wall 12. In other words, the protrusion of this embodiment can be a ring-shaped protrusion structure protruding outward from the bottom wall 12 as shown in FIG. 3 or

FIG. 4A. Alternatively, as shown in FIG. 4B, a plurality of protrusions 32 extend outward on the bottom wall 12, and the plurality of protrusions 32 are not connected together. Certainly, in an unillustrated embodiment, part of the protrusions 32 can be connected together, while some of the protrusions 32 are not connected together. In addition, the protrusions 32 can be arranged at the same or different positions adjacent to the edge side or inside of the bottom wall 12, and can be adjusted depending on the actual product.

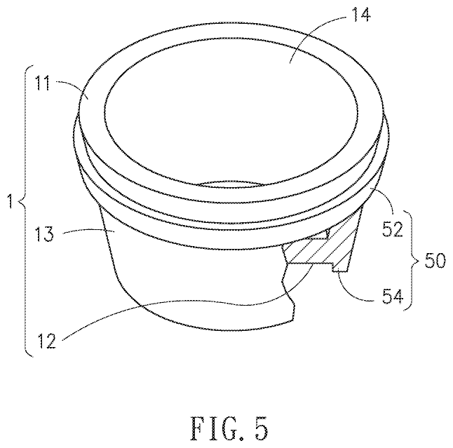

FIG. 5 is a schematic diagram of the other embodiment of the crucible of the present invention. Please refer to FIG. 5; it should be noted that the crucible of FIG. 3 is similar to the crucible of FIG. 1 and the crucibles of FIG. 3, in which the same components are denoted by the same reference numerals and have the same functions, and the description will not be repeated. The outer wall surface of the crucible in FIG. 5 is the bottom wall 12 and the outer wall 13 of the crucible body 1, and the protrusion 50 includes a first protrusion 52 and a second protrusion 54. The first protrusion 52 is a first ring-shaped protrusion structure protruding outward from the outer wall 13, and the first ring-shaped protrusion structure is formed by the first protrusion 52 around the circumferential direction of the outer wall 13. The second protrusion 54 is a second ring-shaped protrusion structure protruding outward from the bottom wall 12. However, the present invention is not limited thereto. In addition, as shown in FIG. 5, along the axial direction of the crucible body 1, the first protrusion 52 is adjacent to one end of the filling end surface 11. The distance from the first protrusion 52 to the bottom wall 12 is greater than the distance from the first protrusion 52 to the filling end surface 11, so that the first protrusion 52 to is farther away from one end of the bottom wall 12; however, the present invention is not limited thereto. In an unillustrated embodiment, the first protrusion is adjacent to one end of the bottom wall, that is, the distance from the first protrusion to the bottom wall is less than the distance from the first protrusion to the filling end surface. Alternatively, the distance from the first protrusion to the bottom wall is equal to the distance from the first protrusion to the filling end surface.

In an unillustrated embodiment, the first protrusion 52 can also be as shown in the protrusion 22 of FIG. 2B, that is, the number of the first protrusion 52 can be multiple, and the plurality of first protrusions 52 are arranged along the circumferential direction of the outer wall 13. Certainly, part of the first protrusions 52 can be connected together, while some of the first protrusions 52 are not connected together. In addition, the first protrusions 52 can be arranged at the same height position or different height positions adjacent to the bottom wall 12 or far from the bottom wall 12, and can be adjusted depending on the actual product.

In the embodiment, the second protrusion 54 is arranged along the circumferential direction of the bottom wall 12. The second protrusion 54 forms a ring-shaped protrusion structure around the circumferential direction of the bottom wall 12, and the ring-shaped protrusion structure is disposed on the edge side of the bottom wall 12. However, the present invention is not limited thereto. In an unillustrated embodiment, the ring-shaped protrusion structure can be disposed inside the bottom wall 12. In an unillustrated embodiment, the second protrusion 54 can also be as shown in the protrusion 32 of FIG. 4B, that is, the number of the second protrusion 54 can be multiple, and the plurality of second protrusion 54 are arranged along the circumferential direction of the bottom wall 12. Certainly, part of the second protrusions 54 can be connected together, while some of the second protrusions 54 are not connected together. In addition, the second protrusions 54 can be arranged at the same or different positions adjacent to the edge side or inside of the bottom wall 12, and can be adjusted depending on the actual product.

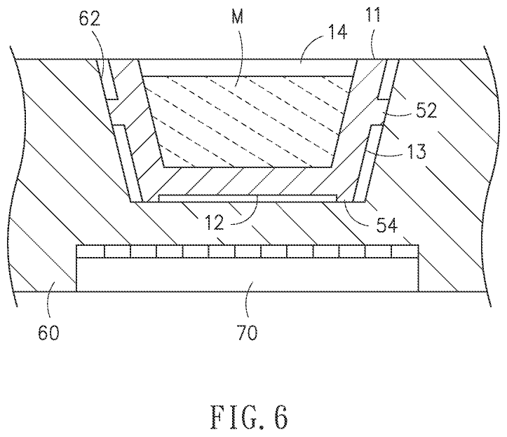

FIG. 6 is a schematic diagram of an embodiment of the vapor deposition apparatus of the present invention. Please refer to FIG. 6; the crucible shown in FIG. 1 to FIG. 5 of this embodiment is used for a vapor deposition process. The present invention does not limit the type of vapor deposition apparatus. The vapor deposition apparatus includes a metal base 60 and a crucible as shown in FIGS. 1 to 5. A tank 62 is provided in the metal base 60, and the metal base 60 is an oxygen-free copper base. The crucible can be contained in the tank 62. And, the containing groove 14 of the crucible body 1 is used for adding a vapor deposition material M. The vapor deposition apparatus uses a heating source 70 to heat the vapor deposition material M in the crucible body 1. In an embodiment, the heating source 70 can be an electron beam, that is, an electron beam is used to heat the vapor deposition material M in the crucible body 1. Since the first protrusion 52 and the second protrusion 54 abut against the inner wall of the tank 62 in the metal base 60, no matter how the crucible is placed, the crucible can be kept in the middle position of the metal base 60. And, the crucible will not deviate, nor will one side of the crucible lean against the wall of the oxygen-free copper base. Therefore, when the crucible is used, the materials in the crucible can be uniformly heated, and the power can be stably controlled, the service life of the crucible can be improved, and the production cost can be reduced. The crucible shown in FIG. 5 is taken as an example above, and the crucible shown in FIGS. 1 to 4 can also be used in the above-mentioned vapor deposition apparatus.

In summary, in the crucible and the vapor deposition apparatus of the present invention, a protrusion is provided on the outer wall of the crucible, and the outer wall surface can be the outer wall or bottom wall of the crucible body. In this way, no matter how the crucible is placed in the metal base, by the protrusion abutting against the inner wall of the metal base, the crucible can be kept in the middle position of the metal base. And, the crucible will not deviate, nor will one side of the crucible lean against the wall of the oxygen-free copper base. Therefore, when the crucible is used, the materials in the crucible can be uniformly heated, and the power can be stably controlled.

The above is intended to be illustrative only and not limiting. Any other equivalent modifications or alterations of the present invention are intended to be included in the scope of the appended claims. Therefore, the protection scope of the present invention shall be subject to those defined by the attached claims.

What is claimed is:

1. A crucible, comprising:
a crucible body, having a containing groove; and
at least one protrusion, disposing on an outer wall or a bottom wall of the crucible body, wherein the each protrusion is a ring-shaped protrusion structure protruding outward from the outer wall and the bottom wall of the crucible body.

2. The crucible as recited in claim 1, wherein the each protrusion is arranged along the circumferential direction of the outer wall.

3. The crucible as recited in claim 1, wherein the each protrusion is arranged along the circumferential direction of the bottom wall.

4. The crucible as recited in claim 1, wherein the each protrusion comprises a first protrusion and a second protrusion, the first protrusion is arranged along the circumferential direction of the outer wall, and the second protrusion is arranged along the circumferential direction of the bottom wall.

5. The crucible as recited in claim 1, wherein the crucible body includes a filling end surface, the containing groove is connected to the filling end surface, and the outer wall is connected between the filling end surface and the bottom wall.

6. A vapor deposition apparatus, comprising:
a metal base; and
the crucible of the claim 1, disposing in the metal base, wherein the each protrusion abuts the inner wall of the metal base, and the containing groove is used for adding a vapor deposition material.

7. The vapor deposition apparatus as recited in claim 6, wherein the metal base is a copper base.
